(19) United States
(12) Patent Application Publication
(10) Pub. No.: US 2025/0143139 A1
(43) Pub. Date: May 1, 2025

(54) TITANIUM ALLOY FOIL, DISPLAY PANEL, AND METHOD FOR MANUFACTURING DISPLAY PANEL

(71) Applicants: NIPPON STEEL CORPORATION, Tokyo (JP); NIPPON STEEL Chemical & Material Co., Ltd., Tokyo (JP)

(72) Inventors: Narumi KONDO, Tokyo (JP); Keiichi KIMURA, Tokyo (JP); Kazuhiro TAKAHASHI, Tokyo (JP); Takuya HIRAGA, Tokyo (JP)

(73) Assignees: NIPPON STEEL CORPORATION, Tokyo (JP); NIPPON STEEL Chemical & Material Co., Ltd., Tokyo (JP)

(21) Appl. No.: 18/722,658

(22) PCT Filed: Dec. 22, 2022
(86) PCT No.: PCT/JP2022/047311

§ 371 Date: Jun. 21, 2024

(30) Foreign Application Priority Data
Dec. 24, 2021 (JP) 2021-210993

(51) Int. Cl. H10K 59/80; C22C 14/00; H10K 59/12; H10K 102/00

(52) U.S. Cl. CPC H10K 59/87; C22C 14/00; H10K 59/1201; C22C 2200/00; H10K 2102/311

(57) ABSTRACT

A titanium alloy foil, wherein when a thickness is represented by t, the t is 0.005 mm or more and 0.200 mm or less, in X-ray diffraction intensities obtained when X-ray diffraction is performed on a surface, a peak intensity of a 200 plane of a crystal of a body-centered cubic structure is 5.0 times or larger a maximum peak intensity from other crystal structures, in X-ray diffraction intensities of the crystal of the body-centered cubic structure among the X-ray diffraction intensities, the peak intensity of the 200 plane or a peak intensity of a 211 plane is larger than a peak intensity of a 110 plane, and a tensile strength is 1,000 MPa or more and 1,800 MPa or less.

### TECHNICAL FIELD OF THE INVENTION

The present invention relates to a titanium alloy foil, a display panel, and a method for manufacturing the display panel.

Priority is claimed on Japanese Patent Application No. 2021-210993, filed on Dec. 24, 2021, the content of which is incorporated herein by reference.

### RELATED ART

Bendable light emitting elements, particularly organic EL elements, have been developed, and in recent years, electronic devices called foldable devices in which the screen itself can be folded or rollable devices that can be rolled in a roll shape and stored have been developed (hereinafter, in a case where it is not necessary to distinguish between foldable devices and rollable devices, both of these may be collectively referred to as foldable devices). Since organic EL elements themselves have no stiffness, a reinforcing sheet is required on their back surfaces in many cases.

The reinforcing sheet is attached to a light emitting element using an adhesive or the like and folded together with the light emitting element. Therefore, the reinforcing sheet needs to be flexible and a thin stainless-steel sheet or stainless-steel foil is mainly selected. Such a reinforcing sheet is required to have bending fatigue durability. Specifically, it means that no bending habit is formed due to repeated bending, and no cracks occur and also no fracture occur due to metal fatigue. Therefore, although the required characteristics are close to those required for a spring material, unlike a spring material, there is not necessarily a requirement for a restoring force.

In Patent Document 1, as a stainless-steel foil that is used for a substrate for a flexible display, a stainless-steel foil in which the average arithmetic average roughness (Ra) in a rolling direction of the foil and a direction perpendicular to the rolling direction is 50 nm or less is invented. In this invention, a relatively large curvature is assumed from the claims. A substrate that is the stainless-steel foil with a circuit thereon with a thin insulating film therebetween is required to have smoothness so as not to impair the resolution of display.

Meanwhile, it has also been proposed to use titanium instead of stainless steel as a substrate of a light emitting device. For example, Patent Document 2 proposes a flexible conductive substrate made of stainless steel or titanium, and an organic light emitting device including a thin film transistor formed on the conductive substrate.

However, the light emitting device relates to a system that biases a conductive substrate. The flexible substrate is required to have conductivity, and repeated bending is not assumed.

In addition, Patent Document 3 describes using a titanium alloy material as a reinforcing material for a light emitting panel such as an organic EL. However, the titanium alloy material is described on the same level with stainless steel that is currently used and plastic, aluminum, and silicone rubber having a generally low strength, and is not assumed to be used while undergoing severe repeated bending that has been required in recent years.

### PRIOR ART DOCUMENT

### [Patent Document]

[Patent Document 1] PCT International Publication No. WO2009/139495
[Patent Document 2] Japanese Unexamined Patent Application, First Publication No. 2007-11256
[Patent Document 3] Japanese Unexamined Patent Application, First Publication No. 2016-75884

### DISCLOSURE OF THE INVENTION

### Problems to be Solved by the Invention

Reinforcing metal sheets or foils to be used for display of recent foldable devices and rollable devices are required to have durability against a large curvature that has not been required in the past. In addition, the sheets or foils may be required to have a larger curvature in a case where these are used as a reinforcing sheet instead of a substrate.

In addition, these electronic devices are required to be thin and light, as is the case with clamshell type, slide type, or tablet mobile phone terminals. Moreover, the curvature for which durability is required is becoming increasingly severe. That is, for the metal material required for the reinforcing sheet, more detailed requirements are required and it is becoming impossible for the current materials to deal with the requirements.

The present invention has been contrived in view of the circumstances, and an object thereof is to provide a material having higher bending fatigue durability, that is alternative to a metal foil currently used as a back reinforcing material for a light emitting element such as a display panel of a foldable device, specifically, a material in which even in a case where bending is repeatedly performed with a large bending angle and a small bend radius (large curvature) unlike before, large fatigue cracks do not occur and a bending habit is small when the material is bent back. Another object of the present invention is to provide a display panel using such a material and a method for manufacturing the display panel.

### Means for Solving the Problem

From the viewpoint of reducing the device weight, the present inventors have conducted studies on the use of a titanium alloy foil having a high specific strength among metals, as a reinforcing material.

As described above, in the related art, a titanium alloy foil has not been considered for use in applications requiring severe repeated bending. The present inventors have conducted further studies, and as a result, found that controlling the texture of a titanium alloy foil to a predetermined state significantly improves the bending fatigue durability.

The present invention has been contrived in view of the above findings. The gist of the present invention is as follows.

[1] A titanium alloy foil according to an aspect of the present invention, in which when a thickness is represented by t, the t is 0.005 mm or more and 0.200 mm or less, in X-ray diffraction intensities obtained when X-ray diffraction is performed on a surface, the peak intensity of a 200 plane of a crystal of a body-centered cubic structure is 5.0 times or larger a maximum peak intensity from other crystal structures, in X-ray diffraction intensities of the crystal of the body-centered cubic structure among the X-ray diffraction intensities, the peak intensity of the 200 plane or the peak intensity of a 211 plane is larger than the peak intensity of a 110 plane, and a tensile strength is 1,000 MPa or more and 1,800 MPa or less.

[2] In the titanium alloy foil according to [1], in the X-ray diffraction intensities, the peak intensity of the 200 plane may be larger than all other peak intensities.

[3] In the titanium alloy foil according to [1], Ra that is an arithmetic average roughness of the surface may be 0.010 μm or more, and Rv that is a maximum valley depth may be 0.180 μm or less.

[4] In the titanium alloy foil according to [2], Ra that is an arithmetic average roughness of the surface may be 0.010 m or more, and Rv that is a maximum valley depth may be 0.180 μm or less.

[5] A display panel according to another aspect of the present invention including: the titanium alloy foil according to any one of [1] to [4]; an adhesive layer that is provided on a surface of the titanium alloy foil; and a light emitting element that is provided on a surface of the adhesive layer.

[6] In the display panel according to [5], the light emitting element may be an organic EL display element.

[7] A method for manufacturing a display panel according to a further aspect of the present invention, including: a step of attaching a light emitting element to the titanium alloy foil according to any one of [1] to [4] with an adhesive layer between the light emitting element and the titanium alloy foil so that a light emitting surface of the light emitting element is an outermost surface.

### Effects of the Invention

According to the aspect of the present invention, it is possible to provide a titanium alloy foil having high bending fatigue durability. By using the titanium alloy foil, it is possible to construct display panels for a foldable electronic device (foldable device) or a rollable electronic device (rollable device) equipped with a flexible light emitting panel that is thin, small, lightweight, and highly durable, and foldable and storable electronic devices such as portable terminals and televisions having the above display panels.

In addition, according to the aspect of the present invention, it is possible to provide a display panel including a titanium alloy foil having high bending fatigue durability and a light emitting element and a method for manufacturing the display panel.

### BRIEF DESCRIPTION OF THE DRAWINGS

FIG. 1 is a diagram showing an example of a display panel for a foldable electronic device.

FIG. 2 is a diagram showing an example of a display panel for a rollable electronic device.

FIG. 3 is a diagram showing an example of a display panel for a rollable electronic device.

FIG. 4 is a diagram showing a clamshell type repeated bending tester.

### EMBODIMENTS OF THE INVENTION

In a titanium alloy foil according to an embodiment of the present invention (the titanium alloy foil according to the present embodiment), when the thickness is represented by t, the t is 0.005 mm or more and 0.200 mm or less, in X-ray diffraction intensities obtained when X-ray diffraction is performed on a surface, the peak intensity of a 200 plane of a crystal of a body-centered cubic structure is 5.0 times or larger than the maximum peak intensity from other crystal structures, in X-ray diffraction intensities of the crystal of the body-centered cubic structure among the X-ray diffraction intensities, the peak intensity of the 200 plane or the peak intensity of a 211 plane is larger than the peak intensity of a 110 plane, and the tensile strength is 1,000 MPa or more and 1,800 MPa or less.

In addition, as an example of application, the titanium alloy foil according to the present embodiment is assumed to be applied to a display panel. For example, in a case where the titanium alloy foil according to the present embodiment is used, it is possible to obtain a display panel (hereinafter, may be referred to as the display panel according to the present embodiment) including the titanium alloy foil according to the present embodiment, an adhesive layer provided on a surface of the titanium alloy foil, and a light emitting element provided on a surface of the adhesive layer.

These will be described.

### [Display Panel]

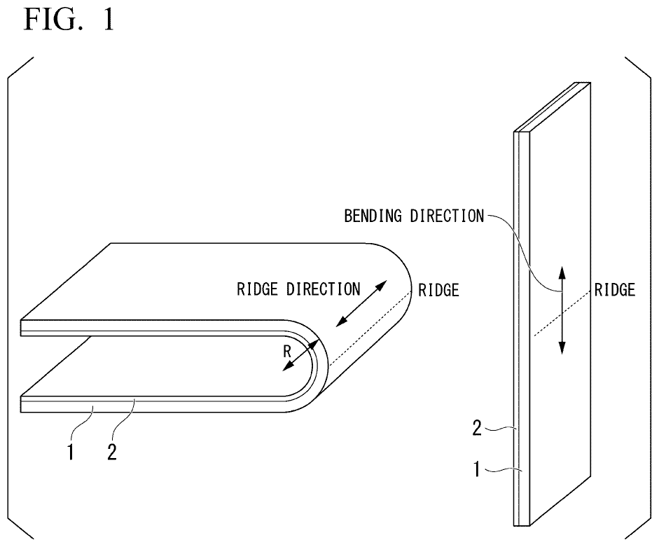

Examples of the display panel according to the present embodiment are shown in FIGS. 1 to 3.

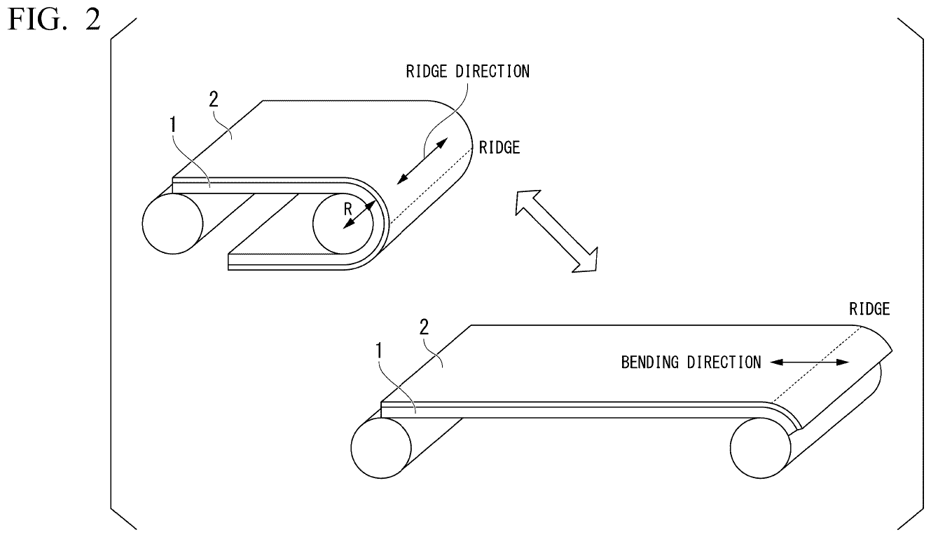

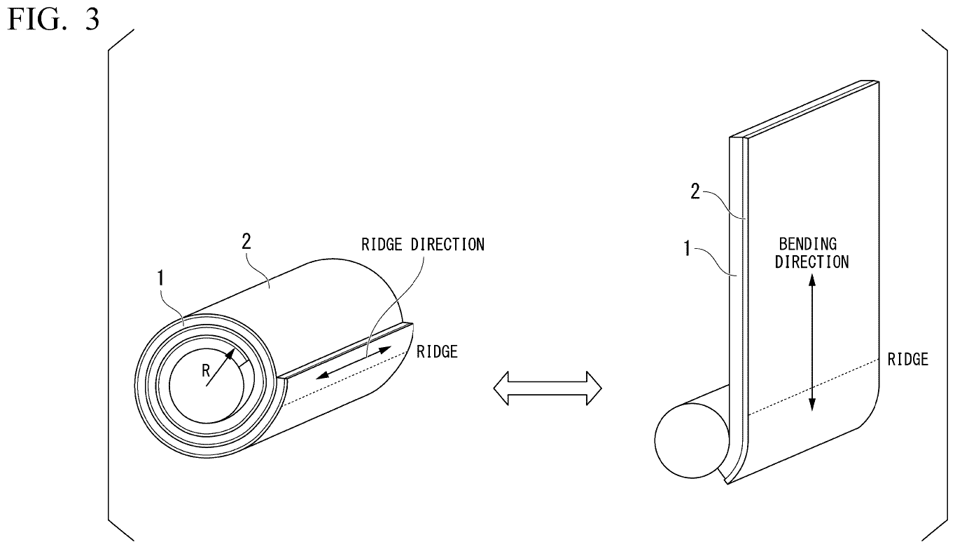

FIG. 1 is an example of a display panel for a foldable electronic device, and FIGS. 2 and 3 are each an example of a display panel for a rollable electronic device. All of these drawings are simplified for the sake of explanation.

In the display panel according to the present embodiment, a titanium alloy foil 1 according to the present embodiment and a light emitting element 2 such as an organic EL element are attached together on the surface using an adhesive or the like (not shown). The light emitting element, the adhesive, and the like are not limited and may be known. The light emitting element is, for example, an organic EL display element.

In FIG. 1, the light emitting element 2 and the titanium alloy foil 1 are attached together so that the light emitting element 2 is on the inside of a bend. However, the light emitting element 2 may be attached to the outer side of the titanium alloy foil 1. Assuming application to foldable devices as shown in FIG. 1, the display panel undergoes repeated bending between a completely closed state and a 180°-open state. That is, the titanium alloy foil of the display panel also undergoes repeated bending between a completely closed state and a 180°-open state.

In this specification, the angle of the repeated bending of the display panel (regarding the titanium alloy foil, the angle of the repeated bending of the titanium alloy foil) is referred to as “unfolding angle”. The closed state is defined as a reference (0°) and referred to as “folding angle”, and the most open state is defined as “opened angle”. That is, “unfolding angle”=“opened angle”−“folding angle” is established. The minimum value of the folding angle is 0°, and the maximum value of the opened angle is 360°. Therefore, the range of the unfolding angles is 0° or more and 360° or less. In FIG. 1, the folding angle is 0°, the opened angle is 180°, and the unfolding angle is 180°.

In applications such as foldable terminals represented by mobile phones, in many cases, these are completely opened and used in a flat state like smartphones from a completely folded state as shown in FIG. 1. In this case, as for the degree of bending to the titanium alloy foil, the folding angle is 0°, the opened angle is 180°, and the unfolding angle is 180°.

The folding angle, the opened angle, and the unfolding angle are not limited to the above numerical values. For example, in applications such as laptop terminals, the unfolding angle does not need to be 180° and the opened angle may be up to about 135° from the viewpoint of the visibility of display.

In the bent form as in FIG. 1, a cross section of the titanium alloy foil 1 is bent into an arc shape having a bend radius R at a bent portion. A complete are may not be formed depending on the restraint with other members and the bend radius. However, the “bend radius R” specified in the present embodiment is a radius of an outer circumferential surface of the titanium alloy foil at a part with the largest curvature imparted to the titanium alloy foil when the central axis of bending and the curved portion on the outer side of the titanium alloy foil are approximated as arcs upon bending as shown in FIG. 1. When R is reduced, the thickness of the electronic device in a folded state can be reduced. Even in a case where the bend radius R is reduced, the display panel using the titanium alloy foil 1 according to the present embodiment has no large fatigue cracks occurring thereon, and its bending habit is small when the display panel is bent back. Therefore, it is useful.

In this specification, the line (the dotted line in FIG. 1) forming a fold when the flat surface of the titanium alloy foil of the display panel is folded in half is referred to as the ridge, and the direction of the ridge is referred to as “ridge direction”. The direction of the ridge is parallel to the central axis of bending. When the foil is returned to a flat surface, a direction perpendicular to the ridge in the flat surface is referred to as “bending direction”.

In the form as in FIG. 1, the bent portion receives bending strain at a local portion in the vicinity of the ridge. Meanwhile, in the rollable displays as in FIGS. 2 and 3, a portion that is repeatedly bent is over almost the entire area of the titanium alloy foil, and the portion that is repeatedly bent changes with time. In the display panel for a rollable device as in FIGS. 2 and 3, the folding angle is 0°, the opened angle is 180°, and the unfolding angle is 180° (the titanium alloy foil also has a folding angle of 0°, an opened angle of 180°, and an unfolding angle of 180°).

In a case where the width is widened for use as shown in FIG. 2, the curvature is constant and a constant radius is defined as the bend radius R (mm). In a case of the form that is used by being rolled in a roll shape as in FIG. 3, the smallest bend radius of the outer circumferential surface of the titanium alloy foil is R (mm). In a case where the bend radius R can be reduced, the display panel for a slide type rollable device as in FIG. 2 can be made thin, and in the winding type rollable display as in FIG. 3, the storage space can be reduced.

Titanium alloy have a lower density than stainless steel and are effective in weight reduction. Titanium alloy foils having sufficient repeated bending characteristics even under severe conditions are useful as materials for a small and lightweight display panel.

### [Titanium Alloy Foil]

Hereinafter, the titanium alloy foil according to the present embodiment will be described in detail.

As described above, the titanium alloy foil according to the present embodiment can be used as a material (a reinforcing sheet of the light emitting element) of the display panel according to the present embodiment.

### <Thickness: 0.005 mm or More and 0.200 mm or Less>

The thickness of a metal foil that is used as a reinforcing sheet of a light emitting element of a foldable display or a rollable device is generally 0.200 mm (200 μm) or less, often 0.150 mm or less, and particularly 0.050 mm or less. Therefore, the thickness of the titanium alloy foil according to the present embodiment is adjusted to 0.200 mm (200 μm) or less. The thickness of the titanium alloy foil is preferably 0.150 mm or less, more preferably 0.100 mm or less, even more preferably 0.070 mm or less, and still more preferably 0.050 mm or less.

Titanium foils having a thickness of 0.200 mm or less have not been used as sheet springs requiring a restoring force or in applications in which the unfolding angle in repeated bending is more than 900 due to the thickness and the low Young's modulus that is a characteristic of titanium. However, the inventors have conducted intensive studies, and as a result, found that, as will be described later, a titanium alloy foil having a strength of 1,000 MPa or more and having a structure mainly including a body-centered cubic structure has extremely excellent bending fatigue durability against repeated bending with a small bend radius (large curvature) even when having a thickness of 0.200 mm or less.

Therefore, the titanium alloy foil according to the present embodiment is a titanium alloy foil having flexibility necessary for repeated bending with an unfolding angle of more than 90° in the foil surface and having a thickness of 0.200 mm or less.

The thickness of the titanium alloy foil according to the present embodiment is 0.005 mm or more in order to reinforce the light emitting element. The thickness is more preferably 0.010 mm or more, and even more preferably 0.020 mm or more.

<In X-Ray Diffraction Intensities Obtained when X-Ray Diffraction is Performed on Surface, Peak Intensity of 200 Plane of Crystal of Body-Centered Cubic Structure is 5.0 Times or Larger Maximum Peak Intensity from Other Crystal Structures>

The titanium alloy foil according to the present embodiment has a texture formed from the viewpoint of bending fatigue durability against repeated bending.

Specifically, in the titanium alloy foil according to the present embodiment, when an X-ray diffraction intensity is measured from the foil surface perpendicular to the thickness direction, the peak intensity from the 200 plane from the titanium alloy having a body-centered cubic structure is 5.0 times or larger a maximum peak intensity from titanium alloy phases having other crystal structures. Among other crystal structures, an α phase or a ω phase of a close-packed hexagonal crystal structure usually exhibits a maximum peak intensity.

In using under severe bending conditions required in recent years (in applications in which bending is repeatedly performed with a predetermined unfolding angle within the ranges of the bend radius and the sheet thickness assumed in the present embodiment), the material that meets the durability requirement is a β-titanium alloy foil. The phase does not necessarily need to be a single phase and may include other phases such as an α phase and an extremely small ω phase of a close-packed hexagonal crystal structure. However, a β phase is required to be a main phase. A larger peak intensity from the 200 plane from the titanium alloy having a body-centered cubic structure than a maximum peak intensity from titanium alloy phases having other crystal structures indicates that the area ratio of a β phase is large. In the titanium alloy foil according to the present embodiment, the peak intensity of the 200 plane is 5.0 times or larger a maximum peak intensity from other crystal structures as an index of β-titanium having a sufficient β phase area ratio.

<In X-Ray Diffraction Intensities of Crystal of Body-Centered Cubic Structure Among X-Ray Diffraction Intensities, Peak Intensity of 200 Plane or Peak Intensity of 211 Plane is Larger than Peak Intensity of 110 Plane>

In a case where the texture of {001}<110> is developed (in a case where the peak intensity of the 200 plane is large), the strength and the elongation in the rolling direction particularly increase, the elastic limit against strain increases, and thus bending fatigue durability against repeated bending increases.

In a case where the texture of {112}<110> is developed (in a case where the peak intensity of the 211 plane is large), the Young's modulus in the in-plane direction of the foil increases as a whole, and the Young's modulus in a direction (TD) orthogonal to the rolling direction (RD) increases particularly in the foil surface. The integration of orientations with a high Young's modulus in the in-plane direction is suitable for applications in which a stiffness of a soft light emitting element is supplemented by adhering on the surface of the soft light emitting element.

Meanwhile, in a case where the degree of formation of the texture is specified by the result of a wide-angle X-ray diffraction method, in X-ray diffraction intensities of a randomly oriented β-titanium alloy such as a powder, the intensity from the 110 plane is the largest.

In the titanium alloy foil according to the present embodiment, a texture in which at least one of {001}<110> and {112}<110> is developed is formed. Therefore, in the measurement of an X-ray diffraction intensity from the foil surface perpendicular to the thickness direction of the titanium alloy foil, in X-ray diffraction intensities of the crystal of the body-centered cubic structure of the titanium alloy having the body-centered cubic structure, any one of the peak intensity from the 200 plane (the peak intensity of the 200 plane) and the peak intensity from the 211 plane (the peak intensity of the 211 plane) is larger than the peak intensity from the 110 plane (the peak intensity of the 110 plane). This can be said to be an index indicating an increase of crystal grains directed in the 110 direction in the foil surface.

In a case where the texture of {001}<110> is developed, particularly, bending fatigue durability against repeated bending in the rolling direction increases. Therefore, in applications to display panels or the like, the rolling direction is preferably the bending direction.

The texture can be obtained by foil rolling. The titanium alloy foil according to the present embodiment has a body-centered cubic structure, and can obtain a rolled texture in which {001}<110> and {112}<110> are developed by strong cold rolling.

<Preferably, in X-Ray Diffraction Intensities, Peak Intensity of 200 Plane is Larger than Peak Intensities of all Other Planes>

In addition, in the titanium alloy foil according to the present embodiment, the peak intensity from the 200 plane is preferably the largest. This indicates that the texture of {001}<110> is more developed and the reason for this is that due to the orientation relationship, 110 orientations are integrated not only in the rolling direction but also in the TD.

Although the detailed mechanism is not clear, bending fatigue durability is further improved in a case where the peak intensity of the 200 plane is the largest.

As described above, it is possible to obtain a rolled texture in which {001}<110> and {112}<110> are developed by strong cold rolling, and the higher the rolling reduction of cold rolling, the larger the peak intensity of the 200 plane.

Each X-ray diffraction peak intensity (the peak intensity of the 200 plane, the peak intensity of the 211 plane, and the peak intensity of the 110 plane of the crystal of the body-centered cubic structure, and the maximum peak intensity from other crystal structures) is measured by the following method.

A rectangular test material of 10 mm in the width direction and 13 mm in the rolling (RD) direction is collected from the titanium alloy foil, and X-ray diffraction is performed on this test piece by a wide-angle XRD method (Cu bulb, 40 kV, 150 mA). The front and back need not be considered.

In the measurement, RINT 1500 (manufactured by Rigaku Corporation) or an equivalent goniometer is used as a goniometer. Filters and incident monochrome are not used. In addition, both a divergence slit and a scattering slit are lG, a light receiving slit is set to 10.15 mm, and a monochromatic light receiving slit is set to 0.8 mm. As photographing conditions, a scanning speed is set to 5°/min, a sampling width is set to 0.02°, and a scanning range is set to 10° to 100°.

### <Tensile Strength: 1,000 MPa or More and 1,800 MPa or Less>

In a case where the titanium alloy foil has strength anisotropy in the in-plane direction, the repeated bending direction during use is limited to a direction in which a tensile strength of 1,000 MPa or more is obtained. The titanium alloy foil according to the present embodiment is required to have a tensile strength of 1,000 MPa or more in the bending direction. The above condition is necessary for both the bending habit and the fracture with respect to repeated bending, and is particularly essential for suppressing the bending habit.

Assuming that the Young's modulus of titanium alloy foils is nearly the same, the presence or absence of the generation of a bending habit is directly specified by the magnitude of a yield strength. However, for example, the yield strength that is represented by proof stress or the like changes depending on the analysis method. Therefore, in the present embodiment, the presence or absence of the generation of a bending habit is specified by the tensile strength (maximum strength).

The tensile strength of the titanium alloy foil according to the present embodiment is 1,000 MPa or more, and preferably 1,100 MPa or more. The upper limit of the tensile strength is not particularly limited. However, in a case where the tensile strength is more than 1,800 MPa, it becomes difficult to roll the foil. Therefore, the upper limit may be 1,800 MPa from the viewpoint of manufacture.

As the strength of the titanium alloy foil according to the present embodiment, a value of a tensile strength obtained in a tensile test is set.

A JIS 13 B test piece is used for the tensile test. The test is performed at a cross-head speed of 50 mm/min while reading the load applied to a load cell by adopting the method based on JIS 2241:2011 “Metallic Materials-Tensile Testing Method of Test at Room Temperature”. A value obtained by dividing the maximum load until fracture by a cross-sectional area of the test piece is defined as the tensile strength.

### [Bending Fatigue Durability Against Repeated Bending]

The titanium alloy foil according to the present embodiment has high bending fatigue durability against repeated bending since the texture and the tensile strength are controlled as described above.

When the titanium alloy foil according to the present embodiment is assumed to be applied to a display panel of a foldable device such as a mobile phone as described above, the titanium alloy foil according to the present embodiment preferably has bending fatigue durability against repeated bending with an unfolding angle of 180°. More specifically, when 180° bending and subsequent returning to 0° are repeated 200,000 times within a range in which R that is a bend radius in millimeters and the t satisfy 65≤R/t≤69, the length of a crack occurring on the surface of the titanium alloy foil is preferably 5 mm or less, and a bending habit in a case where external stress is removed is preferably 170° or more in terms of opened angle. The opened angle is more preferably 175° or more, and even more preferably 180° without bending habit. The crack length specified here refers to the length of a crack having the maximum length in a case where a plurality of cracks are generated.

The titanium alloy foil according to the present embodiment is attached to and used integrally with a flexible light emitting element represented by an organic EL element used in a foldable device. In a case where there is a crack on a surface of the bent portion of the titanium alloy foil, large local deformation occurs, and this may cause abnormality in the display of the light emitting element and may even cause breakage. Accordingly, it is desirable that no cracks occur. However, at most 5 mm can be allowed due to the buffering action of an adhesive layer between the light emitting element and the titanium alloy foil.

Foldable devices are expected to be reduced in size, thickness, and weight in the future, and in the titanium alloy foil according to the present embodiment, a crack introduced into the surface of the titanium alloy foil is preferably 5 mm or less when the titanium alloy foil is subjected to a repeated bending test 200,000 times with an unfolding angle of 180° and R/t=60.

In the measurement of the bending habit, the titanium alloy foil is standed on a flat desk so that the bending ridge is perpendicular to the top plane of the desk, and is then photographed with a digital camera from directly above, in a state of focusing on an upper end portion. Using the image taken as above, the angle of the angled titanium alloy foil is measured. In that case, the opened angle (free opened angle) is measured so that a force such as gravity is not applied in the bending direction of the titanium alloy foil.

The repeated bending test for the titanium alloy foil is performed under conditions of a folding angle of 0° and an opened angle of 180° using a clamshell type repeated bending tester.

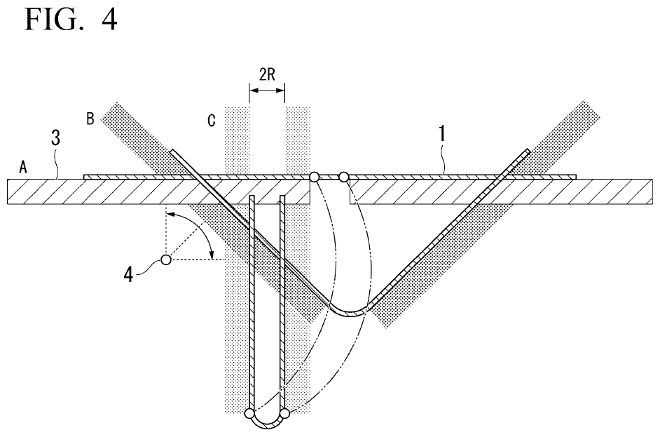

FIG. 4 schematically shows a bending operation in the repeated bending test. The clamshell type repeated bending tester includes a holding sheet 3 formed of a set of two sheets, the titanium alloy foil 1 is attached thereto, and the holding sheet is inclined to give corrected bending displacement to the titanium alloy foil 1. FIG. 4 shows a state A with an opened angle of 180°, a state B that is approximately 90° open, and a state C with a folding angle of 0°.

One of the two sheets of the holding sheet 3 is inclined while rotating around a drive shaft 4, the other holding sheet maintains the same angle, and two lines where corner portions of the upper surfaces of both of the holding sheets are brought into contact with the titanium alloy foil follow while maintaining a constant distance as shown by the dotted lines in FIG. 4. Due to such an operation, the titanium alloy foil can be repeatedly bent so that a load other than bending is not applied thereto. Examples of commercially available evaluation devices that perform such an operation include a no-load clamshell bending tester, manufactured by YUASA SYSTEM CO., LTD., type DR11MR. In addition, the bending fatigue durability against repeated bending may be tested by incorporation into an actual device.

Assuming that the distance between the two holding sheets when the holding sheets are closed is 2R, the titanium alloy foil receives bending displacement so that the arc of the bend radius R is formed. The bent portion may not be in a complete arc depending on the thickness and the mechanical properties of the titanium alloy foil, but in the present embodiment, R is R of the outer circumferential surface of the titanium alloy foil when the bending portion determined by the gap 2R in a state in which the folding angle is 0° in the repeated bending test is regarded as an arc.

In the repeated bending tester, the titanium alloy foil is cut into a size of 40 mm in width and 150 mm in length, and the measurement is performed so that the center of a long side and the width direction are in a bending ridge direction. The width and the length of the titanium alloy foil are measured on a scale with a minimum memory of 0.05 mm and cutting is performed with a tolerance range of ±0.5 mm. For the thickness, using a one-side spherical micrometer having a minimum read value of micrometers or less and having one side flat and one side spherical, the measurement is performed at 10 different points in the sample, and an average value of the measured values is taken up to 0.1 μm.

The gap 2R is set so that R/t is within ±2 of the target R/t. The gap is measured using a limit gauge or a caliper. An image from a direction of the bending central axis with a folding angle of 0° is taken and the gap is measured by the first decimal place in terms of millimeters. In addition, both end parts of the bending ridge are polished using emery paper of #1500 or more before the metal foil is attached to the holding sheet so that cracks are not formed from the end portions of the metal foil. The frequency of repeated bending that determines the bending speed is adjusted to 1 Hz.

R/t is a dimensionless quantity in which the units of the numerator and the denominator are aligned, and is an index indicating the severity of bending considering stress and strain that the material receives. Even in a case where R is the same, the stress and strain that the material receives increases as the thickness (t) of the material increases. Meanwhile, the material is required to have a strength and stiffness according to the use. This has not been seen before in an application form of the metal foil requiring repeated bending fatigue durability with an unfolding angle of 180° and 65≤R/t≤69 as indexes in a preferable titanium alloy foil according to the present embodiment.

The repeated bending with an unfolding angle of 1800 and 65≤R/t≤69 is a preferable condition for specifying the characteristics to be given to the titanium alloy foil according to the present embodiment, and the titanium alloy foil may be used to be repeatedly bent with an angle of more than 90° and 360° or less (for example, an unfolding angle of 135° or more) and R/t of 30 or more and 250 or less in its applications.

It is preferable that, even in a case where the titanium alloy foil is used to be repeatedly bent with an angle of more than 90° and 360° or less (for example, an unfolding angle of 135° or more (135°, 180°, or the like)) and R/t of 30 or more and 250 or less, the length of cracks occurring on the surface of the titanium alloy foil be 5 mm or less when bending is repeated 200,000 times.

In a case where R/t is less than 30, even a foil satisfying other conditions has a large bending habit or does not meet a required fatigue life (cracks occur).

Meanwhile, in a case where R/t is more than 250, even a conventional metal foil that does not satisfy the regulations according to the present embodiment can meet the bending habit and the fatigue life. That is, the curvature and the foil thickness are not within the ranges required for foldable devices and rollable devices, and a general metal foil can be applied.

Permanent deformation (bending habit) after repeated bending is also used as an index of durability. In repeated bending, in a case where the bending habit generated in the bending direction is small, it is corrected by the hinge or frame that configures the electronic device, so that there is no problem. However, in a case where the bending habit becomes large, problems occur such as distortion in the display of a display.

### <Preferably, Arithmetic Average Roughness Ra of Surface: 0.010 μm or More and Maximum Valley Depth Rv: 0.180 μm or Less>

Next, a preferable surface state of the titanium alloy foil according to the present embodiment will be described.

The titanium alloy foil according to the present embodiment is used as a reinforcing material for a light emitting device such as a lighting or a display in which a light emitting element is adhered on a foil surface and that can be folded (bent) in half or rolled in a roll shape. These devices not only form a curved surface, but also undergo repeated bending with a large curvature.

An organic EL element, that is one of light emitting elements, is an element that can provide high-definition display with high color rendering properties, and is used for a display of a high-priced television or mobile phone. In a part where a bending habit or fracture cracks occur in the reinforcing material, the quality of display deteriorates, and thus particularly high durability is required. Therefore, a high tensile strength is required in a specific direction, specifically, in the bending direction.

Since the titanium alloy foil according to the present embodiment is not a substrate on which a light emitting element is directly formed, the titanium alloy foil does not need to be smooth as a surface. However, since the roughness measured in the bending direction affects the bending fatigue durability, the roughness is preferably as small as possible. Meanwhile, in order to prevent peeling of the adhesive that adheres the titanium alloy foil and the light emitting element to each other, it is preferable that certain irregularities is formed to expect an anchor effect.

From the above consideration, regarding the roughness of the titanium alloy foil according to the present embodiment, an arithmetic average roughness Ra that is defined by JIS B 0601 (2001) is preferably 0.010 μm or more and a maximum valley depth Rv is preferably 0.180 μm or less. Rv is more preferably 0.120 μm or less, and even more preferably 0.100 μm or less. The reason why the upper limit of the roughness is the maximum valley depth is that the depth of the recessed part has a greater influence on the bending fatigue durability against repeated bending than the height of the protrusion part of the surface irregularities. The reason why the lower limit of the roughness is the arithmetic average roughness is that average irregularities including peaks and valleys have an influence when considering the adhesive force of the adhesive. From the viewpoint of durability, it is desirable that the roughness be small. Therefore, the above lower limit is preferable in applications limited to the use in adhesion of the surface of the titanium alloy foil.

In the measurement of Rv and Ra, values measured by a stylus method are adopted according to JIS B 0601 (2001). Measurement conditions include a measurement length of 1.25 mm, a cutoff (λc) of 0.25 mm, a cutoff (λs) of 0.0025 mm, a stylus scanning speed of 0.3 mm/sec, and a measurement load of 0.7 mN, and values obtained using a cone with a radius of 2 μmR and a tip angle of 60° as a gauge head are adopted. Rv and Ra can be obtained simultaneously by one measurement. As each of Ra and Rv as indexes in the present embodiment, an average value of values measured at 5 or more different portions on each surface of the titanium alloy foil is adopted. In addition, in a case where there is a large difference in roughness between both surfaces of the titanium alloy foil, the roughness measured on the surface that is larger in Rv and is smaller in Ra, as an unfavorable surface for performance, is adopted.

### <Metallographic Structure>

Next, a preferable crystal structure of the titanium alloy foil according to the present embodiment will be described.

In a case where the titanium alloy foil according to the present embodiment is used in applications in which bending is repeatedly performed with a predetermined unfolding angle within the ranges of the bend radius and the sheet thickness assumed to be applied, the material that meets the durability requirement is required to be a β-titanium alloy foil mainly having a β phase.

Therefore, as described above, in X-ray diffraction intensities obtained when X-ray diffraction is performed on the surface, the peak intensity of the 200 plane of the crystal of the body-centered cubic structure is 5.0 times or larger a maximum peak intensity from other crystal structures.

In a case where many different phases are contained, particularly the to phase is contained, workability deteriorates, and thus a defective metal foil with waviness or wrinkles, or a metal foil that is embrittled, leading to deterioration of toughness and poor durability, may be produced. The titanium alloy foil according to the present embodiment is required to have bending fatigue durability against repeated bending and is characterized in that the thickness thereof is small, and the proportion of phases different from the β phase is preferably small.

The room temperature stable phase of pure titanium is α-titanium having a close-packed hexagonal crystal structure, and α-titanium is a titanium alloy that is commonly used commercially.

The reason why the β-titanium alloy foil mainly including a body-centered cubic structure is particularly preferable as the titanium alloy foil according to the present embodiment is that durability for when repeated bending is applied with small bending can be increased. In order to obtain durability against bending, the strength is required. A β-titanium alloy can easily increase a cold rolling reduction ratio and can obtain a high strength in a state of being made into a foil. In addition, the β-titanium alloy foil has a lower Young's modulus than other high-strength metal foils such as stainless steel and also has a slightly lower Young's modulus than an α-titanium foil. Due to this characteristics, the elastic limit increases against certain bending strain even in a case where the strength is the same, and a bending habit when bending is performed with a large curvature is less likely to occur.

For a metal foil that is used as a reinforcing sheet of a light emitting element of a foldable display or a rollable device, a restoring force is not required as in a case of a sheet spring at the time of bending back and rather the restoring force is preferably small. Therefore the β-titanium alloy foil having the low young's modulus is suitable due to the unique characteristics. In addition, from the viewpoint of device weight reduction, a titanium alloy foil having a lighter specific gravity is suitable among metals.

### <Chemical Composition>

Next, a preferable chemical composition of the titanium alloy foil according to the present embodiment will be described.

The alloy system of the titanium alloy according to the present embodiment is not particularly limited as long as it is an alloy system to be a β-titanium alloy mainly including a body-centered cubic structure, and the effects can be obtained regardless of the chemical composition. For the alloy system to be a β-titanium alloy mainly including a body-centered cubic structure, the Mo equivalent calculated by Mo equivalent (mass %)=Mo+0.67×V+0.44×W+0.28×Nb+0.22×Ta+2.9×Fe+1.6×Cr−1.0×Al by using the amounts of the elements by mass % is preferably 5.0 (mass %) or more. The Mo equivalent is more preferably 10.0 (mass %) or more (an element symbol in the expression indicates the amount of each element contained in the titanium alloy by mass %).

Examples of the alloy system that can meet the requirements include Ti-15V-3Cr-3Sn-3Al, Ti-20V-4Al-1Sn, Ti-22V-4Al, Ti-15V-6Cr-4Al-1Fe, Ti-13V-11Cr-3Al, Ti-3Al-8V-6Cr-4Mo-4Zr, Ti-4.5Fe-6.8Mo-1.5Al, Ti-8V-5Fe-1Al, Ti-16V-4Al, Ti-15Mo-5Zr, Ti-15Mo-5Zr-3Al, T-15Mo-3Al, Ti-7.5V-8Cr-1.6Fe-3.5Sn-3Al, Ti-20V-4Al-1Sn, Ti-22V-4Al, Ti-10V-2Fe-3Al, Ti-8Mo-8V-2Fe-3Al, and Ti-11.5Mo-6Zr-4.5Sn (in the above description, for example, Ti-15V-3Cr-3Sn-3Al indicates that the representative values of the main alloy contents are as follows: V: 15%; Cr: 3%; Sn: 3%; and Al: 3% with a remainder of a Ti alloy including Ti and impurities).

The alloying element used in these alloys is an element that acts to stabilize the β phase of a body-centered cubic structure and improves the strength with respect to pure titanium in which the α phase of a hexagonal close-packed structure is stable at room temperature normally. Since it is difficult to obtain sufficient phase stability and the required strength with the element alone, a multicomponent alloy is selected.

Furthermore, Ti-36Nb-2Ta-3Zr-0.30, Ti-47Nb-3Ta-4Zr-0.30, Ti-34Nb-23Ta-11Zr-3V-0.30, and Ti-9Nb-12Ta-6Zr-3V-0.30 are alloy systems having a large elastic range and are suitable as the titanium alloy foil according to the present embodiment. The compositions of the above alloys are expressed by mass %. The component values are representative values of essential elements. Tolerance may be allowed in manufacturing and inevitable impurities may be contained.

More specifically, for example, Ti-15V-3Cr-3Sn-3Al may have a composition containing, by mass %: V: 14.0% to 16.0%, Cr: 2.5% to 3.5%, Sn: 2.5% to 3.5%, Al: 2.5% to 3.5%, Fe: 1.00% or less, O: 0.25% or less, N: 0.15% or less, C: 0.15% or less, and a remainder of Ti and impurities.

In the Ti-15V-3Cr-3Sn-3Al alloy, vanadium, chromium, tin, and aluminum are used to stabilize the β phase at room temperature and to facilitate cold working while ensuring the strength. Iron (Fe), oxygen (O), nitrogen (N), and carbon (C) are elements that are easily contained as impurity, and managing the contents to a certain extent is effective for cost reduction. Iron is a β phase stabilizing element. It contributes to solid solution strengthening and has an effect of increasing the strength. Oxygen, nitrogen, and carbon also contribute to solid solution strengthening and act to increase the strength.

In addition, as another example, Ti-36Nb-2Ta-3Zr-0.3O may have a composition containing, by mass %: Nb: 33.0% to 38.5%; Ta: 1.5% to 2.5%; Zr: 2.5% to 3.5%; O: 0.05% to 1.3%; Fe: 1.00% or less; N: 0.15% or less; C: 0.15% or less; and a remainder of Ti and impurities.

In a case where each of niobium (Nb), tantalum (Ta), and zirconium (Zr) is within the above component range, large elastic strain exceeding 1% can be obtained with a high strength required for the titanium alloy foil according to the present embodiment. In addition, cold working can be performed with a high working ratio of 90% or more in a rolling step for rolling into a foil having a sheet thickness of 0.200 mm or less. Meanwhile, preferable management ranges for iron, carbon, and nitrogen as impurity elements and the reasons for these are the same as those of Ti-15V-3Cr-3Sn-3Al. Meanwhile, in order to obtain high cold workability, the oxygen strengthening action can be positively used.

In addition, the above-described titanium alloys are specified in, for example, ASTM Gr.6, AMS 4910, AMS 4926, AMS 4966, AMS 4919, AMS 4975, AMS 4976, ASTM GR.5, AMS 4906, AMS 4918S, AMS 4914, AMS 4917B, and AMS 4977.

The chemical composition can be analyzed by a known method such as ICP-AES.

Next, a method for manufacturing the titanium alloy foil according to the present embodiment will be described.

The method for manufacturing the titanium alloy foil according to the present embodiment varies depending on the alloy system, but the titanium alloy foil can be obtained by a manufacturing method including: performing softening annealing as necessary on a known titanium alloy sheet (sheet material) with an alloy system in which the Mo equivalent is 5.0 (mass %) or more; and performing cold rolling.

Hereinafter, preferable requirements for each step will be described.

### [Softening Annealing]

Softening annealing may be performed prior to cold rolling. Softening annealing is preferably performed since the hardness of the titanium alloy decreases and cold rolling under conditions to be described later is facilitated. From this point of view, as softening annealing conditions, a highest heating temperature is preferably 700° C. or higher and a soaking time (holding time) at the highest heating temperature is preferably 5 seconds or longer for softening to hardness with which rolling is possible. The required time varies depending on the alloy system and the highest heating temperature, but there is no problem as long as the hardness is controlled so that rolling is possible. It is desirable to select the holding time in accordance with the alloy system to be produced and the highest heating temperature condition. For example, in a case where the Mo equivalent is 10.0 (mass %) or more, the soaking time is more preferably 30 seconds or longer.

Meanwhile, in performing softening annealing, in a case where the softening annealing is performed at a temperature of 400° C. or higher and lower than 700° C., an α phase and a ω phase causing embrittlement may be precipitated due to the temperature significantly lower than a β transus temperature of the alloy system, and target bending fatigue durability against repeated bending may not be obtained.

Meanwhile, in a case where the highest heating temperature for softening annealing is higher than 1,000° C., the titanium alloy softens more than necessary, and a predetermined tensile strength cannot be obtained after cold rolling. Therefore, in performing softening annealing, the highest heating temperature is adjusted to 1,000° C. or lower.

In addition, in a case where the highest heating temperature is high, the grain size excessively increases and homogenization is not achieved. As a result, the titanium alloy after cold rolling decreases in flatness and increases in roughness. In a case of decreasing the roughness, the highest heating temperature is preferably adjusted to be low. For example, the highest heating temperature is 950° C. or lower or 900° C. or lower.

Also, in a case where the soaking time is longer than 100 seconds, the grain size excessively increases and homogenization is not achieved. As a result, the titanium alloy after cold rolling decreases in flatness and increases in roughness. Therefore, the soaking time is adjusted to 100 seconds or shorter.

The heat treatment time can be controlled by a sheet threading speed or the like.

### [Cold Rolling]

In cold rolling, the sheet material that has been subjected to softening annealing as necessary is cold-rolled to obtain a titanium alloy foil having a thickness of 0.005 to 0.200 mm. By performing cold rolling under predetermined conditions, it is possible to achieve high-strengthening and develop a preferable texture.

In a case where the cumulative rolling reduction is less than 30%, a predetermined texture cannot be developed. In addition, the strength cannot be sufficiently increased. Therefore, the cumulative rolling reduction is adjusted to 30% or more. The cumulative rolling reduction is preferably 50% or more. The upper limit of the cumulative rolling reduction is not limited. However, as the cumulative rolling reduction increases, the rolling becomes difficult. In addition, Rv may increase in a case where the cumulative rolling reduction is too high. Therefore, the cumulative rolling reduction may be adjusted to 95% or less.

The cold rolling may be temporarily interrupted in the middle of the course and annealing may be performed. In that case, the cumulative rolling reduction is a cumulative rolling reduction after final annealing (that is, a softening heat treatment).

In addition, since the surface roughness changes depending on the number of passes (the pass number), the number of passes is preferably controlled in a case of controlling the roughness.

Specifically, in a case where the number of passes is five or more, Rv can be decreased. Therefore, the number of passes is preferably adjusted to 5 or more. The number of passes is more preferably 25 or more.

Meanwhile, in a case where the number of passes is more than 40, Ra decreases. The reason for this is considered to be that since the surface is subjected to rolling while slightly subjected to reduction, Ra decreases. Therefore, by adjusting the number of passes to 40 or less, the maximum valley depth Ra can be adjusted to 0.010 μm or more.

In addition, in cold rolling, the roughness of a rolling roll has a direct influence on the roughness of the titanium alloy foil. Therefore, the rolling roll is preferably a bright roll. In a case where a dull roll is used, Ra can be increased. However, in a case where a bright roll is used and the above-described predetermined number of passes is set, the maximum valley depth Ra can be controlled to 0.010 μm or more while satisfying that the strength is 1,000 MPa or more and Rv is 0.180 μm or less.

Oil marks are likely to be formed continuously in the TD perpendicular to the rolling direction. In the titanium alloy foil according to the present embodiment, the rolling direction is preferably used as the bending direction of a foldable device. However, irregularities in the rolling direction due to the oil marks have a great influence in the direction on the repeated bending fatigue durability for when the device is bent in the rolling direction and used.

By conducting the rolling at the following very low speed and a sheet threading speed of 5 m/min or less, the oil marks are suppressed, the discharge of rolling oil is improved and it becomes possible to adjust the maximum valley depth Rv to 0.180 μm or less while obtaining a strength of 1000 MPa or more, which is preferable.

After the cold rolling (cold rolling for foil manufacturing), no heat treatment such as annealing is performed (the foil is left as cold-rolled).

In a case where a heat treatment is performed after the cold rolling, the flatness of the foil is impaired. In addition, there may be a case where a predetermined texture cannot be obtained. In the foil manufacturing, it is advantageous that the foil is manufactured as cold-rolled. In addition, in a case where annealing is performed, there is a concern that the tensile strength may decrease.

The heat treatment conditions and the cold rolling conditions are not uniquely determined since these vary depending on the capacity and specifications of the manufacturing equipment, such as the rolling load and the sheet threading speed. However, in order to obtain excellent durability suppressing fracture related to repeated bending and a bending habit by adjustment to the preferable strength, structure, and surface roughness according to the present invention, careful consideration is required on the premise of a titanium alloy foil having a small sheet thickness.

A display panel according to the present embodiment can be obtained by attaching the light emitting element to the titanium alloy foil obtained by the above-described method with an adhesive layer between the light emitting element and the titanium alloy foil so that a light emitting surface of the light emitting element is an outermost surface.

### Examples

Hereinafter, the titanium alloy foil according to the present invention will be described more specifically while describing examples. The examples to be described below are merely examples of the titanium alloy foil according to the present invention, and the flexible titanium alloy foil according to the present invention is not limited to the examples to be described below.

Titanium slabs having a predetermined chemical composition were hot-rolled, cold-rolled, and annealed to manufacture sheet materials having a thickness of 0.8 to 3.0 mm and having a predetermined chemical composition (β153 alloy, β3623 alloy, Ti—Cr, Ti-11.5Mo-6Zr-4.5Sn). In addition, commercially available sheet materials having a thickness of 0.5 to 0.8 mm (SUS430, SUS316, SUS301 (stainless-steel sheet materials) specified in JIS G 4305:2012 “Cold-Rolled Stainless-steel sheet, Sheet And Strip”, and TR-270C, 6Al-4V, Ti-6Al-6V-2Sn (titanium alloy sheet materials) were prepared.

Analytical values of the chemical composition of the β153 alloy by mass % were as follows: V: 14.9%; Cr: 2.9%; Al: 2.8 mass %; Sn: 3.0%; and Fe: 0.18%, O: 0.114%, H: 0.024%, C: 0.006%, and N: 0.006% as impurity elements (Mo equivalent=11.7).

In addition, analytical values of the chemical composition of the β623 alloy by mass % were as follows: Nb: 35.3%; Ta: 2.9%; Zr: 2.73%; O: 0.256%; and Fe: 0.03%, Cr: 0.007%, Al: 0.009%, V: 0.006%, H: 0.023%, C: 0.018%, and N: 0.022% as impurity elements (Mo equivalent=10.5).

In addition, analytical values of the chemical composition of Ti-13V-11Cr-3Al described as Ti—Cr by mass % were as follows: V: 12.7%; Cr: 11.0%; Al: 2.9%; and Fe: 0.02%, H: 0.022%, C: 0.009%, and N: 0.017% as impurity elements (Mo equivalent=22.0).

In addition, analytical values of the chemical composition of Ti-11.5Mo-6Zr-4.5Sn by mass % were as follows: Mo: 11.4%; Zr: 5.9%; Sn: 4.5%; and Fe: 0.04%, Cr: 0.01%, Al: 0.012%, V: 0.003%, H: 0.043%, C: 0.022%, and N: 0.021% as impurity elements (Mo equivalent=12.0).

On these sheet materials, a softening heat treatment (not performed on some of the sheets) and cold rolling (cold rolling for foil manufacturing) were performed under conditions shown in Tables 1 to 4 to obtain alloy foils (stainless-steel foils or titanium alloy foils) having a thickness of 0.030 to 0.250 mm. A bright roll was used for cold rolling. In some of the examples, a heat treatment (TA) was performed at 200° C. to 700° C. after the cold rolling for foil manufacturing. In addition, in some other examples, the surface was imparted with a roughness by polishing after the cold rolling for foil manufacturing.

In the cold rolling for foil manufacturing during the manufacturing, as a way to increase the cold rolling reduction ratio so as to obtain the strength and keep the titanium alloy foil smooth except for No. 31, the rolling speed in the rolling step for rolling into a foil of 0.10 mm or less was reduced to 3 m/min in order to suppress oil marks formed due to the excessive rolling oil caught between the roll and the foil during the cold rolling and discharged in the TD.

In addition, in order to measure the foil thickness, using a one-side spherical digital micrometer capable of performing measurement up to 1 μm, manufactured by Mitutoyo Corporation, type: BMS-25MX, the thickness was measured at 10 different points and the average thereof was set as the foil thickness.

TABLE 1

| | | | | Manufacturing Conditions | | | | | | | |
|---|---|---|---|---|---|---|---|---|---|---|---|
| | | | | | | | Cold Rolling for Foil | | | | |
| | | Sheet Material | | Softening Heat Treatment | | | Manufacturing | | | | |
| | Invention | Abbreviated | | Highest | Sheet | | Sheet | Cumulative | | Other | |
| | Example/ | Name for | Mo | Heating | Threading | Soaking | Threading | Rolling | Number | Manu- | Foil |
| Sample | Comparative | Component | Equivalent | Temperature | Speed | Time | Speed | Reduction | of Passes | facturing | Thickness |
| No. | Example | System | mass % | ° C. | m/min | sec | m/min | % | number | Conditions | mm |
| 1 | Comparative | SUS430 | — | — | — | — | — | — | — | — | 0.050 |
| | Example | | | | | | | | | | |
| 2 | Comparative | SUS316 | — | — | — | — | — | — | — | — | 0.050 |
| | Example | | | | | | | | | | |
| 3 | Comparative | SUS301 | — | — | — | — | — | — | — | — | 0.050 |
| | Example | | | | | | | | | | |
| 4 | Comparative | TR-270C | — | — | — | — | — | — | — | — | 0.050 |
| | Example | | | | | | | | | | |
| 5 | Invention | β153 | 11.7 | 850 | 0.33 | 100 | 4 | 50 | 15 | — | 0.050 |
| | Example | | | | | | | | | | |
| 6 | Comparative | β153 | 11.7 | 850 | 0.33 | 100 | 4 | 20 | 15 | — | 0.030 |
| | Example | | | | | | | | | | |
| 7 | Invention | β153 | 11.7 | 850 | 0.33 | 100 | 4 | 40 | 15 | — | 0.030 |
| | Example | | | | | | | | | | |
| 8 | Invention | β153 | 11.7 | 850 | 0.33 | 100 | 4 | 50 | 15 | — | 0.030 |
| | Example | | | | | | | | | | |
| 9 | Invention | β153 | 11.7 | 750 | 0.33 | 100 | 4 | 60 | 15 | — | 0.050 |
| | Example | | | | | | | | | | |
| 10 | Invention | β153 | 11.7 | 750 | 0.33 | 100 | 4 | 60 | 15 | — | 0.075 |
| | Example | | | | | | | | | | |
| 11 | Invention | β153 | 11.7 | 750 | 0.33 | 100 | 4 | 60 | 12 | — | 0.100 |
| | Example | | | | | | | | | | |
| 12 | Invention | β153 | 11.7 | 750 | 0.33 | 100 | 4 | 60 | 12 | — | 0.150 |
| | Example | | | | | | | | | | |
| 13 | Invention | β153 | 11.7 | 750 | 0.33 | 100 | 4 | 60 | 8 | — | 0.200 |
| | Example | | | | | | | | | | |
| 14 | Comparative | β153 | 11.7 | 750 | 0.33 | 100 | 4 | 60 | 7 | — | 0.250 |
| | Example | | | | | | | | | | |
| 15 | Invention | β153 | 11.7 | 700 | 0.33 | 100 | 4 | 50 | 15 | — | 0.040 |
| | Example | | | | | | | | | | |
| 16 | Invention | β153 | 11.7 | 750 | 0.33 | 100 | 4 | 50 | 15 | — | 0.040 |
| | Example | | | | | | | | | | |
| 17 | Invention | β153 | 11.7 | 800 | 0.33 | 100 | 4 | 50 | 15 | — | 0.040 |
| | Example | | | | | | | | | | |

TABLE 2

| | | | | Manufacturing Conditions | | | | | | | |
|---|---|---|---|---|---|---|---|---|---|---|---|
| | | | | | | | Cold Rolling for Foil | | | | |
| | | Sheet Material | | Softening Heat Treatment | | | Manufacturing | | | | |
| | Invention | Abbreviated | | Highest | Sheet | | Sheet | Cumulative | | Other | |
| | Example/ | Name for | Mo | Heating | Threading | Soaking | Threading | Rolling | Number | Manu- | Foil |
| Sample | Comparative | Component | Equivalent | Temperature | Speed | Time | Speed | Reduction | of Passes | facturing | Thickness |
| No. | Example | System | mass % | ° C. | m/min | sec | m/min | % | number | Conditions | mm |
| 18 | Invention | β153 | 11.7 | 950 | 0.33 | 100 | 4 | 50 | 15 | — | 0.040 |
| | Example | | | | | | | | | | |
| 19 | Invention | β153 | 11.7 | 1000 | 0.33 | 100 | 4 | 50 | 15 | — | 0.040 |
| | Example | | | | | | | | | | |
| 20 | Comparative | β153 | 11.7 | 630 | 0.33 | 100 | 4 | 60 | 15 | — | 0.040 |
| | Example | | | | | | | | | | |
| 21 | Comparative | β153 | 11.7 | 1150 | 0.33 | 100 | 4 | 50 | 15 | — | 0.040 |
| | Example | | | | | | | | | | |
| 22 | Comparative | β153 | 11.7 | 900 | 0.05 | 660 | 4 | 50 | 15 | — | 0.040 |
| | Example | | | | | | | | | | |
| 23 | Comparative | β153 | 11.7 | 700 | 0.05 | 660 | 4 | 50 | 15 | — | 0.040 |
| | Example | | | | | | | | | | |
| 24 | Invention | β153 | 11.7 | 900 | 1.00 | 30 | 4 | 50 | 15 | — | 0.040 |
| | Example | | | | | | | | | | |
| 25 | Invention | β153 | 11.7 | 900 | 0.33 | 100 | 4 | 50 | 5 | — | 0.040 |
| | Example | | | | | | | | | | |
| 26 | Invention | β153 | 11.7 | 900 | 0.33 | 100 | 4 | 50 | 30 | — | 0.040 |
| | Example | | | | | | | | | | |
| 27 | Comparative | β153 | 11.7 | 750 | 0.33 | 100 | 4 | 25 | 5 | — | 0.040 |
| | Example | | | | | | | | | | |
| 28 | Invention | β153 | 11.7 | 750 | 0.33 | 100 | 4 | 60 | 10 | — | 0.040 |
| | Example. | | | | | | | | | | |
| 29 | Invention | β153 | 11.7 | 750 | 0.33 | 100 | 4 | 70 | 20 | — | 0.040 |
| | Example | | | | | | | | | | |
| 30 | Invention | β153 | 11.7 | 750 | 0.33 | 100 | 4 | 80 | 25 | — | 0.040 |
| | Example | | | | | | | | | | |
| 31 | Invention | β153 | 11.7 | 750 | 0.33 | 100 | 50 | 60 | 10 | — | 0.040 |
| | Example | | | | | | | | | | |
| 32 | Comparative | β153 | 11.7 | 800 | 0.33 | 100 | 4 | 60 | 15 | TA200° C. | 0.040 |
| | Example | | | | | | | | | | |
| 33 | Comparative | β153 | 11.7 | 800 | 0.33 | 100 | 4 | 60 | 15 | TA400° C. | 0.040 |
| | Example | | | | | | | | | | |

TABLE 3

| | | | | Manufacturing Conditions | | | | | | | |
|---|---|---|---|---|---|---|---|---|---|---|---|
| | | | | | | | Cold Rolling for Foil | | | | |
| | | Sheet Material | | Softening Heat Treatment | | | Manufacturing | | | | |
| | Invention | Abbreviated | | Highest | Sheet | | Sheet | Cumulative | Number | | |
| | Example/ | Name for | Mo | Heating | Threading | Soaking | Threading | Rolling | of | Other | Foil |
| Sample | Comparative | Component | Equivalent | Temperature | Speed | Time | Speed | Reduction | Passes | Manufacturing | Thickness |
| No | Example | System | mass % | ° C. | m/min | sec | m/min | % | number | Conditions | mm |
| 34 | Comparative | β153 | 11.7 | 800 | 0.33 | 100 | 4 | 60 | 15 | TA500° C. | 0.040 |
| | Example | | | | | | | | | | |
| 35 | Comparative | β153 | 11.7 | 800 | 0.33 | 100 | 4 | 60 | 15 | TA700° C. | 0.040 |
| | Example | | | | | | | | | | |
| 36 | Invention | β153 | 11.7 | 750 | 0.33 | 100 | 4 | 60 | 15 | Roughness is | 0.040 |
| | Example | | | | | | | | | imparted by | |
| | | | | | | | | | | polishing | |
| 37 | Invention | β153 | 11.7 | 750 | 0.33 | 100 | 4 | 60 | 15 | Roughness is | 0.040 |
| | Example | | | | | | | | | imparted by | |
| | | | | | | | | | | polishing | |
| 38 | Invention | β153 | 11.7 | 750 | 0.33 | 100 | 4 | 60 | 55 | — | 0.040 |
| | Example | | | | | | | | | | |
| 39 | Invention | β153 | 11.7 | 750 | 0.33 | 100 | 4 | 60 | 15 | — | 0.050 |
| | Example | | | | | | | | | | |
| 40 | Invention | β153 | 10.5 | — | — | — | 4 | 94 | 40 | — | 0.050 |
| | Example | | | | | | | | | | |
| 41 | Invention | β153 | 10.5 | — | — | — | 4 | 95 | 40 | — | 0.040 |
| | Example | | | | | | | | | | |
| 42 | Invention | β153 | 10.5 | — | — | — | 4 | 95 | 40 | — | 0.040 |
| | Example | | | | | | | | | | |
| 43 | Invention | β153 | 10.5 | 800 | 0.33 | 100 | 4 | 60 | 15 | — | 0.040 |
| | Example | | | | | | | | | | |
| 44 | Comparative | β153 | 10.5 | 800 | 0.33 | 100 | 4 | 25 | 15 | — | 0.040 |
| | Example | | | | | | | | | | |

TABLE 4

| | | | | Manufacturing Conditions |
|---|---|---|---|---|
| | | | | Softening Heat Treatment |
| | | Sheet Material | | Highest |
| | Invention | | Mo | Heating |
| Sample | Example/Comparative | Abbreviated Name for | Equivalent | Temperature |
| No. | Example | Component System | mass % | ° C. |
| 45 | Invention Example | Ti—Cr | 22.0 | 800 |
| 46 | Invention Example | Ti—Cr | 22.0 | 800 |
| 47 | Invention Example | Ti—11.5Mo—6Zr—4.5Sn | 12.0 | 800 |
| 48 | Invention Example | Ti—11.5Mo—6Zr—4.5Sn | 12.0 | 800 |
| 49 | Comparative Example | 6Al—4V | −4.0 | 800 |
| 50 | Comparative Example | Ti—6Al—6V—2Sn | −2.0 | 800 |

| | Manufacturing Conditions | | | | | | |
|---|---|---|---|---|---|---|---|
| | | | Cold Rolling for Foil | | | | |
| | Softening Heat Treatment | | Manufacturing | | | | |
| | Sheet | | Sheet | Cumulative | Number | | |
| | Threading | Soaking | Threading | Rolling | of | Other | Foil |
| Sample | Speed | Time | Speed | Reduction | Passes | Manufacturing | Thickness |
| No. | m/min | sec | m/min | % | number | Conditions | mm |
| 45 | 0.33 | 100 | 4 | 60 | 15 | — | 0.040 |
| 46 | 0.33 | 100 | 4 | 60 | 15 | — | 0.040 |
| 47 | 0.33 | 100 | 4 | 60 | 15 | — | 0.040 |
| 48 | 0.33 | 100 | 4 | 60 | 15 | — | 0.040 |
| 49 | 0.33 | 100 | 4 | 60 | 15 | — | 0.040 |
| 50 | 0.33 | 100 | 4 | 60 | 15. | — | 0.040 |

X-ray diffraction was performed on the surface of the obtained foil in the manner described above to obtain the peak intensity of the 200 plane, the peak intensity of the 211 plane, and the peak intensity of the 110 plane of the crystal of the body-centered cubic structure, and the maximum peak intensity from other crystal structures.

The results are shown in Tables 5 to 8.

In addition, the tensile strength of the obtained foil was measured.

For a tensile test, a test piece having a shape conforming to a JIS 13 B test piece with a length of 150 mm was cut out from the metal foil manufactured as described above, and the test was performed at a cross-head speed of 50 mm/min with a contact strain gauge having a gauge length of 50 mm. The rolling direction (RD) was set as a test direction. The load until fracture was monitored with a load cell, and a value obtained by dividing the maximum load by a cross-sectional area of the sample before the test was defined as the tensile strength. As the tensile strength, the average of the values measured in 5 test pieces was set.

The results are shown in Tables 5 to 8.

In addition, the roughness (Ra, Rv) of the obtained foil was measured.

In the roughness measurement, arbitrary ranges at different portions on the surface of the foil manufactured as described above were measured in accordance with JIS B0601 (2001) by using a stylus type surface roughness measuring instrument (with a desktop anti-vibration table), manufactured by Tokyo Seimitsu Co., Ltd., type: SURFCOM 480B. Measurement conditions included a measurement length of 1.25 mm, a cutoff (λc) of 0.25 mm, a cutoff (λs) of 0.0025 mm, a stylus scanning speed of 0.3 mm/sec, and a measurement load of 0.7 mN. A cone with a tip radius of 2 μm and an opened angle of 60° was used as a gauge head. The rolling direction was set as a measurement direction. In the present roughness measurement, a roughness curve was obtained from a contour curve, that is a displacement profile of the gauge head performing the measurement in one direction according to irregularities of the foil surface, and an arithmetic average roughness (Ra) and a maximum valley depth (Rv) as roughness indexes of the metal foil according to the present invention were derived. The measured values of Ra and Rv were measured at arbitrary 5 different portions on the surface of the metal foil, and an average value of the measured values at the 5 points was adopted. The roughness measurement was performed on the front and back surfaces of the foil, and a smaller value of Ra and a larger value of Rv were used as the roughness indexes of the foil.

The results are shown in Tables 5 to 8.

TABLE 5

| | | Foil | | | | | | |
|---|---|---|---|---|---|---|---|---|
| | | | X-Ray Diffraction Intensity Obtained When X-Ray | | | | | |
| | | | Diffraction is Performed on Surface | | | | | |
| | | | | | Peak Intensity | | | |
| | | | | Maximum Peak | of 200 Plane/ | | | |
| | Invention | | Plane Exhibiting | Intensity/Peak | Maximum Peak | Tensile | Roughness | |
| Sample | Example/Comparative | Included | Maximum X-Ray | Intensity from | Intensity of Other | Strength | Ra | Rv |
| No. | Example | Phase | Diffraction Peak | 110 Plane | Crystal Structures | MPa | μm | μm |
| 1 | Comparative Example | — | — | — | — | 1110 | 0.023 | 0.095 |
| 2 | Comparative Example | — | — | — | — | 1146 | 0.021 | 0.149 |
| 3 | Comparative Example | — | — | — | — | 1387 | 0.022 | 0.114 |
| 4 | Comparative Example | α | α002 | — | — | 903 | 0.023 | 0.087 |
| 5 | Invention Example | β | β211 | 3.7 | 7.5 | 1076 | 0.024 | 0.084 |
| 6 | Comparative Example | β | β110 | 1.0 | 9.0 | 920 | 0.041 | 0.078 |
| 7 | Invention Example | β | β211 | 2.4 | 10.0 | 1024 | 0.021 | 0.089 |
| 8 | Invention Example | β | β200 | 4.7 | 18.8 | 1126 | 0.022 | 0.099 |
| 9 | Invention Example | β | β211 | 12.2 | 21.0 | 1105 | 0.023 | 0.089 |
| 10 | Invention Example | β | β211 | 11.5 | 23.5 | 1101 | 0.019 | 0.091 |
| 11 | Invention Example | β | β211 | 17.1 | 23.5 | 1100 | 0.022 | 0.092 |
| 12 | Invention Example | β | β211 | 13.7 | 40.8 | 1073 | 0.024 | 0.085 |
| 13 | Invention Example | β | β211 | 14.0 | 22.0 | 1066 | 0.031 | 0.095 |
| 14 | Comparative Example | β | β200 | 16.2 | 21.0 | 1030 | 0.032 | 0.090 |
| 15 | Invention Example | β | β211 | 3.4 | 12.5 | 1121 | 0.018 | 0.063 |
| 16 | Invention Example | β | β200 | 9.1 | 28.9 | 1107 | 0.022 | 0.095 |
| 17 | Invention Example | β | β200 | 5.5 | 19.8 | 1102 | 0.032 | 0.122 |

TABLE 6

| | | Foil | | | | | | |
|---|---|---|---|---|---|---|---|---|
| | | | X-Ray Diffraction Intensity Obtained When | | | | | |
| | | | X-Ray Diffraction is Performed on Surface | | | | | |
| | | | | | Peak Intensity | | | |
| | | | | | of 200 Plane/ | | | |
| | | | | Maximum Peak | Maximum Peak | | | |
| | Invention | | Plane Exhibiting | Intensity/Peak | Intensity of | Tensile | Roughness | |
| Sample | Example/Comparative | Included | Maximum X-Ray | Intensity from | Other Crystal | Strength | Ra | Rv |
| No. | Example | Phase | Diffraction Peak | 110 Plane | Structures | MPa | μm | μm |
| 18 | Invention Example | β | β211 | 8.7 | 28.9 | 1068 | 0.034 | 0.128 |
| 19 | Invention Example | β | β211 | 22.3 | 55.0 | 1054 | 0.045 | 0.150 |
| 20 | Comparative Example | β + α + ω | β211 | 2.2 | 3.5 | 1010 | 0.030 | 0.010 |
| 21 | Comparative Example | β | β200 | 47.2 | 21.2 | 959 | 0.046 | 0.180 |
| 22 | Comparative Example | β | β200 | 1.0 | 25.3 | 970 | 0.075 | 0.126 |
| 23 | Comparative Example | β + α | β200 | 0.9 | 4.7 | 988 | 0.056 | 0.116 |
| 24 | Invention Example | β | β200 | 9.6 | 22.1 | 1102 | 0.024 | 0.091 |
| 25 | Invention Example | β | β200 | 6.9 | 24.0 | 1020 | 0.045 | 0.140 |
| 26. | Invention Example | β | β200 | 15.2 | 23.2 | 1050 | 0.024 | 0.091 |
| 27 | Comparative Example | β | β211 | 1.0 | 17.5 | 983 | 0.021 | 0.092 |
| 28 | Invention Example | β | β211 | 12.3 | 17.8 | 1102 | 0.022 | 0.093 |
| 29 | Invention Example | β | β200 | 20.2 | 17.3 | 1149 | 0.019 | 0.089 |
| 30 | Invention Example | β | β200 | 27.5 | 18.3 | 1187 | 0.034 | 0.120 |
| 31 | Invention Example | β | β211 | 12.1 | 17.8 | 1187 | 0.075 | 0.210 |
| 32 | Comparative Example | β + α | β211 | 3.2 | 1.0 | 1018 | 0.028 | 0.100 |
| 33 | Comparative Example | β + α | β211 | 0.9 | 1.2 | 1015 | 0.029 | 0.110 |

TABLE 7

| | | Foil | | | | | | |
|---|---|---|---|---|---|---|---|---|
| | | | X-Ray Diffraction Intensity Obtained When | | | | | |
| | | | X-Ray Diffraction is Performed on Surface | | | | | |
| | | | | | Peak Intensity | | | |
| | | | | | of 200 Plane/ | | | |
| | | | | Maximum Peak | Maximum Peak | | | |
| | Invention | | Plane Exhibiting | Intensity/Peak | Intensity of | Tensile | Roughness | |
| Sample | Example/Comparative | Included | Maximum X-Ray | Intensity from | Other Crystal | Strength | Ra | Rv |
| No. | Example | Phase | Diffraction Peak | 110 Plane | Structures | MPa | μm | μm |
| 34 | Comparative Example | β + α | β211 | 0.8 | 3.5 | 1005 | 0.034 | 0.220 |
| 35 | Comparative Example | β | β211 | 1.0 | 77.6 | 1067 | 0.021 | 0.120 |
| 36 | Invention Example | β | β211 | 16.2 | 17.3 | 1092 | 0.062 | 0.300 |
| 37 | Invention Example | β | β211 | 16.2 | 17.3 | 1092 | 0.078 | 0.700 |
| 38 | Invention Example | β | β211 | 9.6 | 15.5 | 1089 | 0.009 | 0.063 |
| 39 | Invention Example | β | β211 | 12.2 | 21.0 | 1105 | 0.023 | 0.089 |
| 40 | Invention Example | β | β200 | >100 | >100 | 1140 | 0.034 | 0.140 |
| 41 | Invention Example | β | β200 | >100 | >100 | 1181 | 0.028 | 0.121 |
| 42 | Invention Example | β | β200 | >100 | >100 | 1181 | 0.029 | 0.121 |
| 43 | Invention Example | β | β211 | >100 | >100 | 1005 | 0.027 | 0.120 |
| 44 | Comparative Example | β | β211 | >100 | >100 | 818 | 0.026 | 0.120 |

TABLE 8

| | | Foil | | | | | | |
|---|---|---|---|---|---|---|---|---|
| | | | X-Ray Diffraction Intensity Obtained When | | | | | |
| | | | X-Ray Diffraction is Performed on Surface | | | | | |
| | | | | | Peak Intensity | | | |
| | | | | | of 200 Plane/ | | | |
| | | | | Maximum Peak | Maximum Peak | | | |
| | Invention | | Plane Exhibiting | Intensity/Peak | Intensity of | Tensile | Roughness | |
| Sample | Example/Comparative | Included | Maximum X-Ray | Intensity from | Other Crystal | Strength | Ra | Rv |
| No. | Example | Phase | Diffraction Peak | 110 Plane | Structures | MPa | μm | μm |
| 45 | Invention Example | β | β211 | 1.8 | 15.2 | 1100 | 0.026 | 0.120 |
| 46 | Invention Example | β | β211 | 1.6 | 15.0 | 1100 | 0.028 | 0.120 |
| 47 | Invention Example | β | β211 | 1.4 | 8.8 | 1013 | 0.024 | 0.120 |
| 48 | Invention Example | β | β211 | 1.2 | 9.7 | 1012 | 0.025 | 0.120 |
| 49 | Comparative Example | α + β | β211 | 0.9 | 0.7 | 960 | 0.021 | 0.120 |
| 50 | Comparative Example | α + β | β211 | 0.7 | 1.2 | 1100 | 0.026 | 0.120 |

In addition, the obtained foil was subjected to a repeated bending test and bending fatigue durability was evaluated based on the presence or absence of the occurrence of fatigue cracks and a bending habit when the foil was bent back.

As a sample for the repeated bending test, a sample having a size of 40 mm in width and 100 mm in length and aligned in a length direction was cut out from the manufactured foil.

In the repeated bending test, a no-load clamshell bending tester, manufactured by YUASA SYSTEM CO., LTD., type DR11MR was used. In the length direction of the sample set as a bending direction, 180° bending and closing and subsequent 180° returning and opening were repeated at the center. The bending curvature can be changed by adjusting the gap during the bending and closing, and as shown in FIG. 4, by setting the gap to 2R, a bending portion having a bend radius R is formed. The cycle of repeated bending was set to 1 Hz. The test was performed until the number of times of repeated bending reached 200,000.

A sample having no cracks formed thereon at a time when 200,000 times of repeated bending had been finished was determined as crack evaluation A, a sample in which even one crack of 5 mm or more had occurred was determined as crack evaluation D, a sample in which a maximum crack length was 3 mm or more and less than 5 mm was determined as crack evaluation C, and a sample in which cracks were recognized but a maximum crack length was less than 3 mm was determined as crack evaluation B. In particular, in the samples determined as crack evaluation D and crack evaluation C, a plurality of cracks occurred in some cases. In these case, the maximum crack length is set to a reference for determination based on the intended use of the metal foil according to the present invention. Those determined as evaluation D were determined as unacceptable and others were determined as acceptable.

With respect to the samples that did not completely fracture after 200,000 times, these were removed from the test jig so that a large force was not applied to the test piece, and the free opened angle remaining on the metal foil was measured. In a case where the metal foil is laid down, the opened angle changes depending on its own weight. Therefore, the metal foil was standed on a flat desk so that the bending ridge was perpendicular to the top plane of the desk, and was then photographed with a digital camera from directly above, focusing on an upper end portion. Using the image taken as above, the angle (bending habit) of the angled metal foil was measured. In a case where the bending habit was small and the titanium alloy foil was not standed alone, a sheet was applied to the metal foil from both sides to perform the measurement so that the angle formed due to the bending habit of the metal foil did not change.

A metal foil that had returned to an opened angle of 180° without bending habit was determined as bending habit evaluation A, a metal foil that had returned to an opened angle of 175° or more and less than 180° was determined as bending habit evaluation B, a metal foil that had returned to an opened angle of 170° or more and less than 175° was determined as bending habit evaluation C, and a metal foil that had returned to an opened angle of less than 170°, that is, had a bending habit of 10° or more was determined as bending habit evaluation D. The evaluation D was determined as unacceptable.

Tables 9 to 12 show the evaluation results.

TABLE 9

| | | Foil | | | |
|---|---|---|---|---|---|
| | Invention | Conditions for Repeated Bending | | Results of Repeated Bending | |
| | Example/ | Evaluation | | Evaluation | |
| | Comparative | Bend Radius R | | Crack | Bending Habit |
| Sample No. | Example | mm | R/t | Evaluation | Evaluation |
| 1 | Comparative Example | 3.4 | 67.9 | D | — |
| 2 | Comparative Example | 3.4 | 68.0 | D | — |
| 3 | Comparative Example | 3.4 | 67.7 | D | — |
| 4 | Comparative Example | 3.4 | 68.1 | D | — |
| 5 | Invention Example | 3.4 | 68.1 | A | A |
| 6 | Comparative Example | 2.0 | 66.4 | B | D |
| 7 | Invention Example | 2.0 | 66.7 | B | B |
| 8 | Invention Example | 2.0 | 66.4 | A | A |
| 9 | Invention Example | 3.3 | 66.0 | A | A |
| 10 | Invention Example | 5.0 | 66.0 | A | A |
| 11 | Invention Example | 6.6 | 66.0 | A | A |
| 12 | Invention Example | 9.9 | 66.0 | B | B |
| 13 | Invention Example | 13.2 | 66.0 | B | C |
| 14 | Comparative Example | 16.5 | 66.0 | D | — |
| 15 | Invention Example | 2.6 | 65.0 | A | A |
| 16 | Invention Example | 2.6 | 65.0 | A | A |
| 17 | Invention Example | 2.6 | 65.0 | A | A |

TABLE 10

| | | Foil | | | |
|---|---|---|---|---|---|
| | Invention | Conditions for Repeated Bending | | Results of Repeated Bending | |
| | Example/ | Evaluation | | Evaluation | |
| | Comparative | Bend Radius R | | Crack | Bending Habit |
| Sample No. | Example | mm | R/t | Evaluation | Evaluation |
| 18 | Invention Example | 2.6 | 65.0 | B | B |
| 19 | Invention Example | 2.6 | 65.0 | C | B |
| 20 | Comparative Example | 2.6 | 65.0 | D | — |
| 21 | Comparative Example | 2.6 | 65.0 | D | — |
| 22 | Comparative Example | 2.6 | 65.0 | C | D |
| 23 | Comparative Example | 2.6 | 65.0 | C | D |
| 24 | Invention Example | 2.6 | 65.0 | A | A |
| 25 | Invention Example | 2.6 | 65.0 | C | C |
| 26 | Invention Example | 2.6 | 65.0 | C | C |
| 27 | Comparative Example | 2.6 | 65.0 | C | C |
| 28 | Invention Example | 2.6 | 65.0 | A | A |
| 29 | Invention Example | 2.6 | 65.0 | A | A |
| 30 | Invention Example | 2.6 | 65.0 | A | A |
| 31 | Invention Example | 2.6 | 65.0 | C | C |
| 32 | Comparative Example | 2.6 | 65.0 | D | — |
| 33 | Comparative Example | 2.6 | 65.0 | D | — |

TABLE 11

| | | Foil | | | |
|---|---|---|---|---|---|
| | Invention | Conditions for Repeated Bending | | Results of Repeated Bending | |
| | Example/ | Evaluation | | Evaluation | |
| | Comparative | Bend Radius R | | Crack | Bending Habit |
| Sample No. | Example | mm | R/t | Evaluation | Evaluation |
| 34 | Comparative Example | 2.6 | 65.0 | D | — |
| 35 | Comparative Example | 2.6 | 65.0 | D | — |
| 36 | Invention Example | 2.6 | 65.0 | B | C |
| 37 | Invention Example | 2.6 | 65.0 | C | C |
| 38 | Invention Example | 2.6 | 65.0 | C | C |
| 39 | Invention Example | 1.6 | 32.0 | C | C |
| 40 | Invention Example | 3.4 | 68.1 | A | A |
| 41 | Invention Example | 2.7 | 67.3 | A | A |
| 42 | Invention Example | 2.4 | 59.9 | A | A |
| 43 | Invention Example | 2.6 | 65.0 | A | A |
| 44 | Comparative Example | 2.6 | 65.0 | A | A |

TABLE 12

| | | Foil | | | |
|---|---|---|---|---|---|
| | Invention | Conditions for Repeated Bending | | Results of Repeated Bending | |
| | Example/ | Evaluation | | Evaluation | |
| | Comparative | Bend Radius R | | Crack | Bending Habit |
| Sample No. | Example | mm | R/t | Evaluation | Evaluation |
| 45 | Invention Example | 2.6 | 65.0 | A | A |
| 46 | Invention Example | 2.6 | 65.0 | A | A |
| 47 | Invention Example | 2.6 | 65.0 | A | A |
| 48 | Invention Example | 2.6 | 65.0 | A | A |
| 49 | Comparative Example | 2.6 | 65.0 | C | D |
| 50 | Comparative Example | 2.6 | 65.0 | D | — |

As can be seen from Tables 1 to 12, in the invention examples, the thickness is within a range of 0.005 mm or more and 0.200 mm or less, in X-ray diffraction intensities obtained when X-ray diffraction is performed on the surface, the peak intensity of a 200 plane of a crystal of a body-centered cubic structure is 5.0 times or larger than the maximum peak intensity from other crystal structures, and in X-ray diffraction intensities of the crystal of the body-centered cubic structure among the X-ray diffraction intensities, the peak intensity of the 200 plane or the peak intensity of a 211 plane is larger than the peak intensity of a 110 plane. In invention examples, the tensile strength is 1,000 MPa or more and 1,800 MPa or less, and the bending fatigue durability is high when repeated bending was performed.

Meanwhile, in the comparative examples, at least one of the thickness, the texture, and the strength is outside the range of the present invention, or they were stainless-steel foil or the like and were not predetermined titanium alloy foil. As a result, the bending fatigue durability is low during repeated bending.

Sample Nos. 1 to 3 were stainless-steel foils obtained using a stainless-steel sheet material, and Sample No. 4 was an α (not body-centered cubic)-titanium foil. The results in the crack evaluation were D.

In Sample No. 6, since the cumulative rolling reduction was insufficient in the cold rolling during the foil manufacturing, the texture was not appropriate (outside the range of the present invention), and the tensile strength was also low.

In Sample No. 14, the titanium alloy foil had a large thickness. As a result, the result in the crack evaluation was D.

In Sample No. 20, the softening heat treatment was performed, but the highest heating temperature was low, so that the texture was not appropriate. As a result, the result in the crack evaluation was D.

In Sample No. 21, the highest heating temperature in the softening heat treatment was high, so that the texture was not appropriate. As a result, the result in the crack evaluation was D. The tensile strength was also low.

In Sample Nos. 22 and 23, the soaking time was too long in the softening heat treatment, so that the textures were not appropriate. As a result, the results in the bending habit evaluation were D. In addition, the tensile strength was also low.

In Sample No. 27, since the cumulative rolling reduction was insufficient, the texture was not appropriate and the tensile strength was also low.

In Sample Nos. 32 to 35, the textures were not appropriate due to the annealing performed after the cold rolling for foil manufacturing. As a result, the results in the crack evaluation were D. These foils also had a poor shape.

In Sample No. 44, since the cumulative rolling reduction was insufficient, the tensile strength was low.

Sample No. 49 is an example in which a material with a low Mo equivalent was used, and the texture was not appropriate. As a result, the result in the bending habit evaluation was D.

In Sample No. 50, since the Mo equivalent was low, the texture was not appropriate, and the tensile strength was also low. The result in the crack evaluation was D.

### INDUSTRIAL APPLICABILITY

According to the present invention, it is possible to provide a titanium alloy foil having high bending fatigue durability. By using the titanium alloy foil, it is possible to construct display panels for a foldable electronic device (foldable device) or a rollable electronic device (rollable device) equipped with a flexible light emitting panel that is thin, small, lightweight, and highly durable, and foldable and storable electronic devices such as portable terminals and televisions having the above display panels, and thus the present invention has high industrial applicability.

### BRIEF DESCRIPTION OF THE REFERENCE SYMBOLS

1 TITANIUM ALLOY FOIL
2 LIGHT EMITTING ELEMENT
3 HOLDING SHEET
4 DRIVE SHAFT
A STATE WITH OPENED ANGLE OF 180°
B STATE THAT IS APPROXIMATELY 90° OPEN
C STATE WITH FOLDING ANGLE OF 0°

1. A titanium alloy foil,
wherein when a thickness is represented by t, the t is 0.005 mm or more and 0.200 mm or less,
in X-ray diffraction intensities obtained when X-ray diffraction is performed on a surface, a peak intensity of a 200 plane of a crystal of a body-centered cubic structure is 5.0 times or larger a maximum peak intensity from other crystal structures,
in X-ray diffraction intensities of the crystal of the body-centered cubic structure among the X-ray diffraction intensities, the peak intensity of the 200 plane or a peak intensity of a 211 plane is larger than a peak intensity of a 110 plane, and
a tensile strength is 1,000 MPa or more and 1,800 MPa or less.

2. The titanium alloy foil according to claim 1,
wherein in the X-ray diffraction intensities, the peak intensity of the 200 plane is larger than all other peak intensities.

3. The titanium alloy foil according to claim 1,
wherein Ra that is an arithmetic average roughness of the surface is 0.010 μm or more, and Rv that is a maximum valley depth is 0.180 μm or less.

4. The titanium alloy foil according to claim 2,
wherein Ra that is an arithmetic average roughness of the surface is 0.010 μm or more, and Rv that is a maximum valley depth is 0.180 μm or less.

5. A display panel comprising:
the titanium alloy foil according to claim 1;
an adhesive layer that is provided on a surface of the titanium alloy foil; and
a light emitting element that is provided on a surface of the adhesive layer.

6. The display panel according to claim 5,
wherein the light emitting element is an organic EL display element.

7. A method for manufacturing a display panel, comprising:
attaching a light emitting element to the titanium alloy foil according to claim 1 with an adhesive layer between the light emitting element and the titanium alloy foil so that a light emitting surface of the light emitting element is an outermost surface.

8. A display panel comprising:
the titanium alloy foil according to claim 2;
an adhesive layer that is provided on a surface of the titanium alloy foil; and
a light emitting element that is provided on a surface of the adhesive layer.

9. A display panel comprising:
the titanium alloy foil according to claim 3;
an adhesive layer that is provided on a surface of the titanium alloy foil; and
a light emitting element that is provided on a surface of the adhesive layer.

10. A display panel comprising:
the titanium alloy foil according to claim 4;
an adhesive layer that is provided on a surface of the titanium alloy foil; and
a light emitting element that is provided on a surface of the adhesive layer.

11. The display panel according to claim 8,
wherein the light emitting element is an organic EL display element.

12. The display panel according to claim 9,
wherein the light emitting element is an organic EL display element.

13. The display panel according to claim 10,
wherein the light emitting element is an organic EL display element.

14. A method for manufacturing a display panel, comprising:
attaching a light emitting element to the titanium alloy foil according to claim 2 with an adhesive layer between the light emitting element and the titanium alloy foil so that a light emitting surface of the light emitting element is an outermost surface.

15. A method for manufacturing a display panel, comprising:
attaching a light emitting element to the titanium alloy foil according to claim 3 with an adhesive layer between the light emitting element and the titanium alloy foil so that a light emitting surface of the light emitting element is an outermost surface.

16. A method for manufacturing a display panel, comprising:
attaching a light emitting element to the titanium alloy foil according to claim 4 with an adhesive layer between the light emitting element and the titanium alloy foil so that a light emitting surface of the light emitting element is an outermost surface.
